(19) United States
(12) Patent Application Publication
(10) Pub. No.: US 2026/0200338 A1
(43) Pub. Date: Jul. 16, 2026

(54) ELECTRIC VEHICLE POWERTRAIN CALIBRATION

(71) Applicant: Secondmind Limited, London (GB)

(72) Inventors: Fergus SIMPSON, London (GB); Victor PICHENY, London (GB); Andrew LIUBINAS, London (GB); Qi QI, London (GB); Andrew CHUNG, London (GB)

(21) Appl. No.: 19/559,453

(22) Filed: Mar. 6, 2026

Related U.S. Application Data
(63) Continuation of application No. PCT/GB2024/052206, filed on Aug. 22, 2024.

(30) Foreign Application Priority Data
Sep. 8, 2023 (GB) 2313760.7

(51) Int. Cl. B60L 15/20; G01R 31/00; G01R 35/00; G06N 7/01

(52) U.S. Cl. CPC B60L 15/20; G01R 31/007; G01R 35/005; G06N 7/01; B60L 2220/14; B60L 2240/421; B60L 2240/423; B60L 2240/425; B60L 2240/429

(57) ABSTRACT

A method includes generating, for an electric vehicle powertrain, a calibration map providing a mapping from values of a set of context variables to mapped values of a set of decision variables. The context variables have values representing the vehicle's operational conditions, and the decision variables have values representing powertrain parameters adjustable by an ECU. The method includes determining the mapped values in dependence on outputs of a Gaussian process model arranged to predict values of a performance characteristic at points in an input space having dimensions corresponding to at least one context variable and at least one decision variable. A covariance function of the Gaussian process model depends on input space points in accordance with a specified physical relationship between the performance characteristic and at least a chosen variable of the decision or context variables.

### CROSS-REFERENCE TO RELATED APPLICATIONS

This application is a continuation under 35 U.S.C. § 120 of International Application No. PCT/GB2024/052206, filed Aug. 22, 2024, which claims priority to United Kingdom Application No. GB 2313760.7, filed Sep. 8, 2023, under 35 U.S.C. § 119 (a). Each of the above-referenced patent applications is incorporated by reference in its entirety

### TECHNICAL FIELD

The present disclosure relates to calibration of an electronic control unit (ECU) for an electric vehicle. The disclosure has particular, but not exclusive, relevance to ECU calibration for the powertrain of an electric vehicle with a Permanent Magnet Synchronous Motor (PMSM).

### BACKGROUND

An electronic control unit (ECU) is a standard component of an automotive vehicle and is critical to the vehicle's efficient performance. The ECU directly controls operation of the vehicle's powertrain by determining values of operational parameters for its components in response to the instantaneous operational conditions and/or driving inputs of the vehicle. A typical ECU has access to mapping data that relates values of one or more context variables representing the instantaneous operational conditions to one or more decision variables representing the operational parameters controlling the powertrain. The mapping data is usually stored in the form of a lookup table from which values can be directly read or interpolated. Obtaining the mapping data for a particular vehicle typically involves a time-consuming calibration process prior to deployment of the ECU in the vehicle, though the mapping data may also be updated or tuned during the vehicle's lifetime, for example to modify performance or to account for variations in performance of the powertrain components.

It is desirable that, for a given set of context variables, the calibration map of the ECU determines values of the set of decision variables corresponding to optimal or near-optimal powertrain performance characteristics or other suchlike variables. The aim of the ECU calibration process is therefore to estimate or approximate a “profile optimum” which is the optimal mapping of any permissible values of the set of context variables to optimal values of the set of decision variables. In an electric vehicle, the powertrain usually includes a battery, an inverter, and an electric motor. It is often desirable for the calibration map to determine the minimum possible current required by the motor to generate a target level of torque specified by the operational conditions of the vehicle. Similarly, it may also be desirable for the calibration map to determine values of decision variables that optimise an efficiency of the powertrain. The calibration process involves measuring, and possibly modelling, performance characteristics such as the torque or the efficiency of the powertrain as a function of the context and decision variables over large parameter spaces. This process can require a large number of expensive and time-consuming experiments on a test bench.

### SUMMARY

According to aspects of the present disclosure, there are provided computer-implemented methods, computing systems comprising means for carrying out the methods, and computer program products (such as one or more non-transient storage media) comprising instructions which, when executed by a computer, cause the computer to carry out the methods.

A first computer-implemented method includes generating a calibration map for a powertrain of an electric vehicle. The calibration map provides a mapping from values of a set of context variables to mapped values of a set of decision variables, wherein the context variables have values representing operational conditions of the electric vehicle, and the decision variables have values representing parameters of the powertrain adjustable by an electronic control unit, ECU, of the electric vehicle. The method includes determining the mapped values of the set of decision variables in dependence on outputs of a Gaussian process model arranged to predict values of a performance characteristic of the powertrain at points in an input space having dimensions corresponding to at least one context variable of the set of context variables and at least one decision variable of the set of decision variables. The Gaussian process model used in the method has a covariance function depending on points in the input space in accordance with a specified physical relationship between the performance characteristic and at least a chosen variable associated with the powertrain, wherein the chosen variable is taken from the set of decision variables or the set of context variables.

Incorporating the specified physical relationship between the performance characteristic and the chosen variable allows prior knowledge of the powertrain to be encoded into the Gaussian process model, enabling the model to capture more accurately and efficiently the variation of the performance characteristic with the context and decision variables, and to require fewer iterations to train, thereby potentially reducing valuable test bench time. By encoding the specified physical relationship into the covariance function, the Gaussian process model is able to faithfully represent any uncertainties and statistical variations associated with the specified physical relationship, whilst also allowing for dependence on variables other than those already included in the specified physical relationship.

A second computer-implemented method includes training a probabilistic model to generate a calibration map for a powertrain of an electric vehicle. The calibration map provides a mapping from values of a set of context variables to mapped values of a set of decision variables, but the context variables further include a temperature variable indicating the temperature of a component of the powertrain. The method includes training the probabilistic model to predict values of a performance characteristic of a powertrain at points in an input space having dimensions corresponding to at least one context variable of the set of context variables and at least one decision variable of the set of decision variables. The method includes a training iteration, in a set of one or more iterations, comprising obtaining a reference value of the temperature variable depending on a measurement of the temperature of the component of the powertrain. The method includes one or more points in a region of the input space in dependence on values of an acquisition function dependent on the probabilistic model, wherein the region of the input space is specified in dependence on the reference value of the temperature variable. The method includes acquiring data indicating, for each point of the selected one or more points, a respective set of measurements of the performance characteristic at values of the at least one context variable and the at least one decision variable corresponding to that point. The method includes updating the probabilistic model in dependence on acquired data, and determining the mapped values of the set of decision variables from the input space in dependences on the outputs of the trained probabilistic model.

By specifying the region of the input space in dependence on the reference value of the temperature variable, the temperature of the component of the powertrain is accessed as a consequence of the transition of the motor between states corresponding to the remaining context and decision variables. Thus, the training method is able to forego active control of the temperature variable, and the temperature is allowed to rise or otherwise vary naturally during the course of the operation of the motor. As a result, the total number of transitions between temperature values attained by the motor is reduced, which can lead to a drastic reduction in the time spent training on a test bench. According to a further aspect, there is provided method including generating a calibration map for a powertrain of an electric vehicle using one of the above methods, and configuring the electric vehicle with the generated calibration map.

Further features and advantages of the invention will become apparent from the following description of preferred embodiments of the invention, given by way of example only, which is made with reference to the accompanying drawings.

### BRIEF DESCRIPTION OF THE DRAWINGS

FIG. 1 is a schematic representing an electric vehicle with an ECU;

FIG. 2 shows an example of a system for calibrating the ECU of an electric vehicle;

FIG. 3 is a schematic showing the variables relevant to calibration of an ECU;

FIG. 4 shows the model variables and the respective constraint variables used in the procedure for calibrating an ECU;

FIG. 5 shows an example method of training a GP model to predict outputs of a powertrain performance characteristic;

FIG. 6 shows an example trajectory for collecting query points in decision space for training a GP model;

FIG. 7 compares the performance of example methods of Bayesian Optimisation used for training a GP model;

FIG. 8 shows example configurations of successive query points in context space for training a GP model.

### DETAILED DESCRIPTION

Details of systems and methods according to examples will become apparent from the following description with reference to the figures. In this description, for the purposes of explanation, numerous specific details of certain examples are set forth. Reference in the specification to ‘an example’ or similar language means that a feature, structure, or characteristic described in connection with the example is included in at least that one example but not necessarily in other examples. It should be further noted that certain examples are described schematically with certain features omitted and/or necessarily simplified for the ease of explanation and understanding of the concepts underlying the examples.

Embodiments of the present disclosure relate to calibration of an electric vehicle powertrain. In particular, embodiments described herein address challenges related to the time-consuming and resource-intensive nature of generating an ECU calibration map resulting from the large parameter space covered by the range of possible operating conditions for an electric vehicle powertrain, such as for a powertrain containing a Permanent Magnet Synchronous Motor (PMSM) driven by an electric battery. To address these challenges, the disclosed methods make use of (i) Gaussian process (GP) models with physics-based modifications, and/or (ii) adapted forms of Bayesian optimisation. Either alone or in combination, these approaches can be used to achieve efficient and accurate calibration of an ECU for an electric vehicle powertrain.

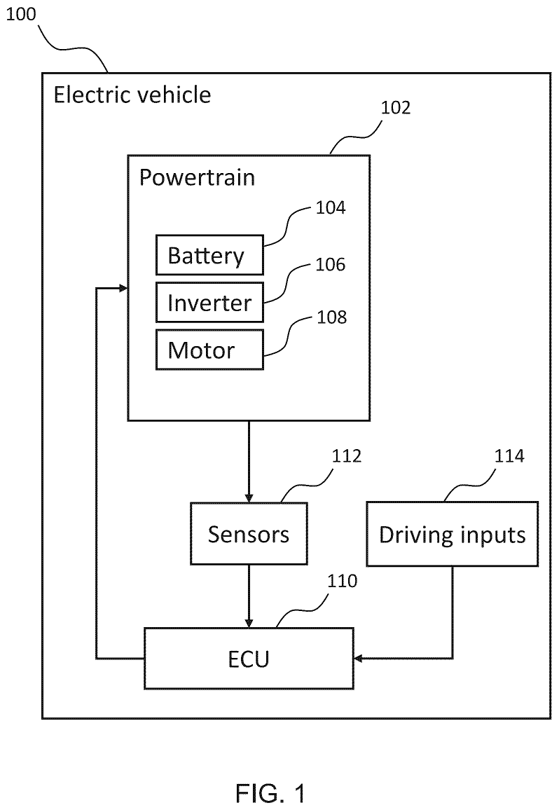

FIG. 1 schematically shows an electric vehicle 100. The electric vehicle 100 may be a production car, a racing car, a truck, a lorry, a motorbike, a motorboat, an aeroplane, a helicopter, an unmanned aerial vehicle (UAV) or drone, or any other type of powered vehicle. The electric vehicle 100 includes a powertrain 102 responsible for generating power that is transferred to certain driven components of the electric vehicle 100. In this example, the powertrain 102 includes a battery 104, an inverter 106, and an electric motor 108. The battery 104 may be a chargeable electric battery, such as a lithium-ion or a lithium-ion polymer battery, or any other appropriate type of battery for generating a direct voltage and supplying direct current. The battery 104 may include electrochemical cell such as a fuel cell for converting chemical energy into the electrical energy corresponding to the direct current. The inverter 106 may include one or more components of a power inverter for converting the direct current supplied by the battery 104 into an alternating current. In some examples, the inverter 106 may require an independent power source separate from the battery 104 included in the powertrain 102. The electric motor 108 may be an asynchronous motor or a synchronous motor such as, for example, a Permanent Magnet Synchronous Motor (PMSM) or a variant thereof. In other examples, such as in hybrid vehicles, the powertrain 102 may additionally include an internal combustion engine or a turbine engine and any other suchlike components.

The electric vehicle 100 shown in FIG. 1 further includes an ECU 110. The ECU 110 receives as input a number of parameters for the powertrain 102 using sensors 112 which may be included in the powertrain 102 or its components; alternatively, the sensors 112 may be provided separately from the powertrain 102. The parameters measured by the sensors may include so-called context variables that may be indicative of the operational conditions of the electric vehicle 100. For example, context variables may pertain to parameters of the components of the powertrain 102, including the battery 104, the inverter 106, and the motor 108 or any other components. The current supplied by the battery 104 or the inverter 106 and the torque generated by the motor 108 may be relevant context variables. Context variables may additionally relate to one or more driving inputs 114 corresponding to driving conditions of the electric vehicle 100, such as a target torque resulting from a pedal position and/or a drive transmission setting. In some examples, the driving inputs 114 may correspond to instantaneous driving conditions, but in other examples, integrated or historical measurements relating to driving conditions may be provided by the driving inputs 114. Further, the driving inputs 114 for the electric vehicle 100 may include parameters relating to the driving system or the environment. Such a driving system may include components such as a steering system, gearbox and a driveshaft responsible for transferring the power generated by the powertrain 102 to the driven components of the vehicle. In land-driven vehicles such as cars or trucks, a driven components may include a system of wheels connected to the driveshaft and steering system. The environment of the electric vehicle 100 may include factors such as terrain or features thereof. Driving inputs 114 may be received from a manual driving system configured to receive human input, or from an automated driving system configured to receive inputs from an autonomous driving agent. The ECU 110 may also be configured to receive a combination of manual and computer-generated inputs, for example in the case of an advanced driver assistance system (ADAS). Control over different parameters may be subordinated to different ECUs. In some examples, the ECU 110 may be a centralised computing unit. In other examples, the ECU 110 may be a decentralised system of modules controlling respective sets of parameters. For example, in a hybrid vehicle the ECU 110 may include a module for controlling the charging/discharging of rechargeable batteries, and a module for controlling power distribution between motors/engines. The ECU 110 may be configured to receive both driving inputs 114 and the inputs from the sensors 112 and, in turn, determine outputs that control subsequent operation of the powertrain 102. Such outputs of the ECU 110 may include values of so-called decision variables that may be determined in dependence on a variety of inputs including at least some of the context variables. The aim of calibrating an ECU 110 is to determine, for a given set of inputs, a set of outputs that provides a high (or low) value of a given objective while satisfying any relevant constraints. The objective or constraints may quantify or otherwise relate to a performance characteristic such as torque generated by the motor 108 or efficiency of the powertrain 102. Calibrating the ECU 110 to determine suitable values of the control outputs may therefore be guided by consideration of the operational mechanism of the powertrain 102.

In the powertrain 102 of the electric vehicle 100, the battery 104 may generate a direct current and a direct voltage. The direct current generated by the battery 104 may be converted by the inverter 106 into an alternating current, which may be supplied to the electric motor 108. In various examples, the amplitude of the alternating current supplied by the inverter 106 may determine the strength of a magnetic field generated in a stator of the electric motor 108. The magnetic field generated in the stator may be configured to interact with a magnetic field generated in a rotor of the electric motor 108. The interaction of the magnetic field of the stator and the rotor may result in the generation of a torque. In a Permanent Magnet Synchronous Motor (PMSM), the rotor contains a permanent magnet and the magnetic field generated by the stator rotates nearly synchronously relative to the rotor. In this context, the advance angle of the alternating current (indicated by the relative angle between the stator's magnetic field and the rotor's magnetic field) may determine a mode of operation of the powertrain 102. For positive advance angles, the powertrain 102 may operate so as to generate torque causing the electric vehicle 100 to accelerate. For negative advance angles, the powertrain 102 may operate in a regenerative braking mode, in which the electric vehicle 100 decelerates and the braking causes charging of the battery 104. For a given set of driving inputs 114 and inputs from the sensors 112, a sub-optimal setting of the amplitude and advance angle of the alternating current may lead to an undesirable level of acceleration or an undesirable amount of energy loss in the form of heat, thereby reducing the efficiency of the electric vehicle 100. Similarly, at elevated temperatures of the electric motor 108 during operation, the magnetic field of the rotor may be weakened such that a significantly greater amplitude of alternating current may be required by the electric motor 108 to generate a target amount of torque determined by the driving inputs 114. As a result, values of the amplitude of the alternating current (indicative of the torque generated) and the advance angle of the alternating current (indicative of the mode of operation) may affect the efficiency of the electric vehicle 100 under a given set of operational conditions. Relevant objectives for the efficient operation of the powertrain 102 may include determining the minimum (or as low as possible) amplitude of alternating current for a desired level of torque, or determining the values of the amplitude and advance angle of the alternating correlating with a high efficiency of the powertrain 102 for given values of context and decision variables. In general, the alternating current may be represented or parameterised using variables other than the amplitude and advance angle. Such variables may, for example, correspond to components of the alternating current vector in orthogonal directions. Alternatively, the variables may be associated with the alternating current through some other means.

An ECU 110 may therefore be configured to determine suitable values of decision variables, such as the amplitude and advance angle of the alternating current, with regard to such objectives. A calibrated ECU 110 may include a calibration map for the powertrain 102 that maps values of context variables relating to the operational conditions of the electric vehicle 100 to values of the decision variables. To quantify the outputs that achieve the desired value of the performance characteristic for a given set of inputs, it may be possible to obtain a model of variation of the performance characteristic in dependence on the context variables and decision variables. It is an objective of the present disclosure to efficiently generate a calibration map for the powertrain 102 by introducing an accurate probabilistic model for the performance characteristic and presenting a cost-effective method for training the model.

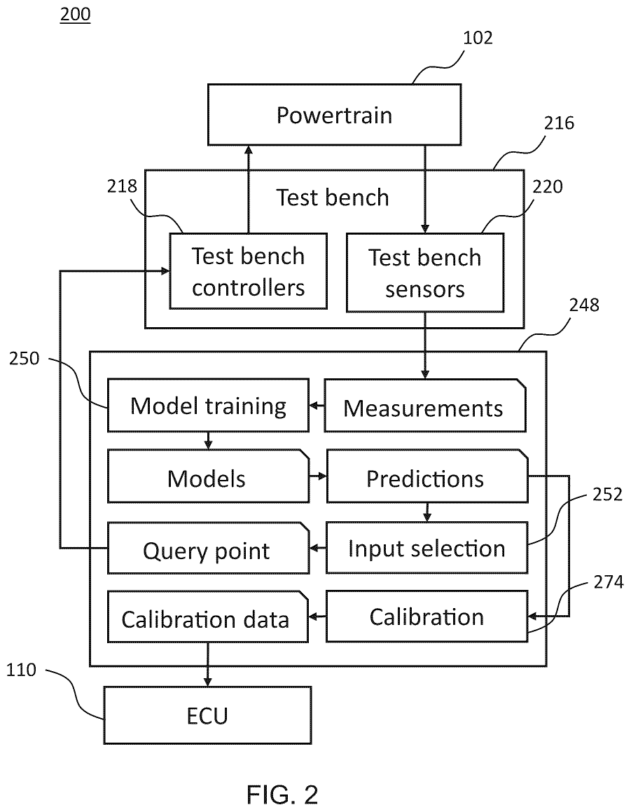

FIG. 2 shows an example of a system 200 for calibrating the ECU 110 of an electric vehicle 100. The system includes a test bench 216, which is a controlled environment for performing experiments on the powertrain 102. The test bench 216 includes test bench controllers 218 and test bench sensors 220. The test bench controllers 218 are devices capable of controlling the parameters of the powertrain 102 which, if the powertrain 102 were installed in the electric vehicle 100, would be controllable by the driving system or an ECU 110. The test bench controllers 218 may further have at least partial control over the environmental factors relevant for calibrating the ECU 110. It may be possible to precisely control certain environmental factors, whereas it may only be possible to partially control other environmental factors. The test bench controllers 218 may include electronic circuits, computer software/hardware components, mechanical actuators and suchlike, which together are capable of fixing values, at least approximately, for the variables that define input and output data for the ECU 110. The test bench sensors 220 may be arranged to measure variables of the powertrain 102 that may affect the performance of the powertrain 102, and thereby the values of its performance characteristics, on the test bench 216.

The test bench sensors 220 and the test bench controllers 218 may be coupled, directly or indirectly, to a data processing system 248, which may be a single computing device such as a desktop computer, laptop computer, or server, or may be distributed across multiple computing nodes, for example based at different locations. The data processing system 248 includes one or more processors and memory comprising one or more non-transient storage media holding machine-readable instructions or program code which, when executed by the one or more processors, cause the data processing system 248 to guide experimentation on the test bench 216 in order to collect data revealing how the performance characteristics measured by the test bench sensors 220, and to train the probabilistic models necessary for determining the values of the relevant variables as set by the test bench controllers 218.

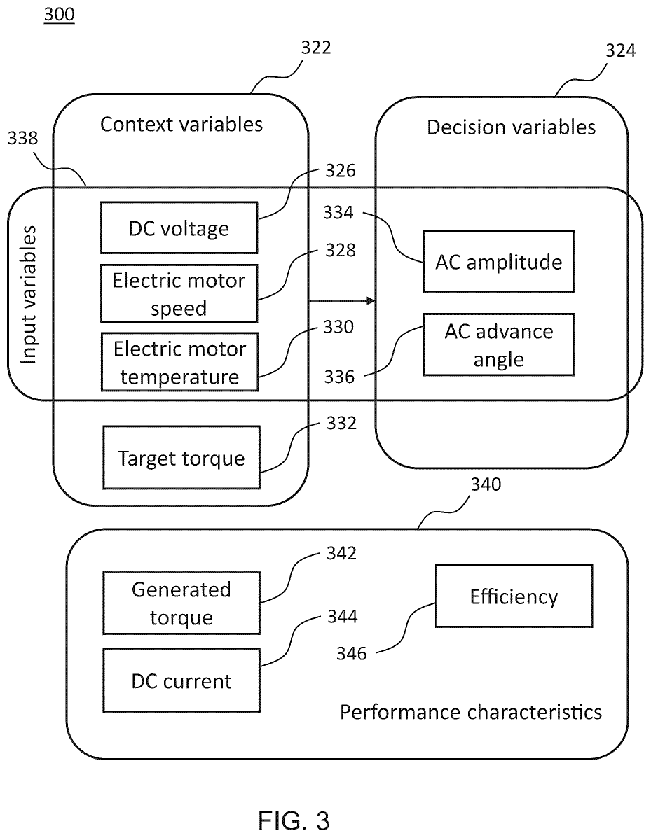

FIG. 3 is a schematic showing an example of variables 300 that may be relevant to calibration of the ECU 110. The set of context variables 322 include variables that are indicative of the operational conditions of the electric vehicle 100. The variables included in the set of context variables 322 may be both measured by sensors 112 as well controlled by the controllers, for example during the calibration procedure, by the test bench controllers 218. The set of context variables 322 may include, for example, parameters relating to components of the powertrain 102 as measured by the test bench sensors 220. Considering the operation of the powertrain 102 described above, the direct voltage 326 generated by the battery 104 and the electric motor speed 328 may be included in the set of context variables 322. Additionally, the temperature 330 of the electric motor 108 may be included in the set of context variables 322. The set of context variables 322 may also include variables relating to driving inputs 114 such as, for example, a target torque 332 determined by the driving system of the electric vehicle 100. Values of one or more variables in the set of context variables 322 may be mapped by the ECU 110 to values of variables in a set of decision variables 324.

The set of decision variables 324 includes variables that affect the operation of the powertrain 102 and are directly controllable by the ECU 110. In this example, the amplitude 334 of the alternating current, or AC amplitude, and the advance angle 336 of the alternating current, or AC advance angle, are considered as decision variables 324. The ECU 110 may thus be configured to determine values of the AC amplitude 334 and the AC advance angle 336 in relation to each combination of values of the DC voltage 326, the electric motor speed 328, the electric motor temperature 330 and the target torque 332. As discussed hereinbefore, operating a PMSM with suitable values of the AC amplitude 334 and the AC advance angle 336 with respect to a performance characteristic may result in improved performance of the powertrain 102. In other examples, a fewer or a greater number of parameters relating to the powertrain 102 may be considered as context variables 322 or decision variables 324.

Given the context and decision variables associated with ECU 110, a method is needed for determining suitable values of the decision variables 324 for each set of context variables 322. As discussed above, this may be achieved using an objective function that evaluates a given combination of the decision variables 324 and context variables 322. In this example, the objective function evaluates a set of input variables 338 such that the objective function may be defined over an input space having dimensions corresponding to the input variables 338. In FIG. 3, the input variables 338 are shown as a subset of the context variables 322 and the decision variables 324. In this example, the input variables 338 include the context variables DC voltage 220, electric motor speed 322 and electric motor temperature 324, and the decision variables AC amplitude 328 and AC advance angle 330. Thus, each point in the input space is determined by values of these five input variables 338 that act as coordinates of the input space. It will be appreciated that the context variables and decision variables set out in FIG. 3 are exemplary and in other examples different sets of context variables and/or decision variables may be considered. The relationship between the input variables and the context and decision variables may also differ in other examples. For example, one or more of other context variables, such as the electric motor temperature 330, may be excluded from the input space to reduce the dimensionality of the optimisation problem described hereinafter.

As explained above, the aim of calibrating the ECU 110 is to determine, for a given set of context variables 322, a set of decision variables 324 that provides a high (or low) value of a given objective function in the input space while satisfying any relevant constraints. Determining suitable values of the objective function may relate to an objective with respect to the operation of the powertrain 102. For example, a high value of the objective function may relate to a better performance of the powertrain 102. Determining suitable values of the objective function in the input space may involve modelling the variation of one or more performance characteristics 340 of the powertrain 102 over the input space.

One objective relating to the operation of the powertrain 102 may include determining a minimum (or as low as possible) supply of current for a target torque 332 specified by the driving conditions. Minimising the current flowing in the stator of a PMSM in the powertrain 102 may reduce heat losses due to resistance and thereby improve the performance of the vehicle 100. In this example, the objective function may correspond the AC amplitude 334 supplied by the inverter 106. It may be possible to model the torque 342 generated by the electric motor 108 in dependence on values of the input variables 338. In order to find a suitable value for the AC amplitude 334, values of the generated torque 342 predicted by the model may be constrained to be approximately equal to the target torque 332. The developed model may then be used to determine a suitably low value of the AC amplitude 334 using the model for the generated torque 342 constrained by values of the target torque 332. As will be discussed in detail below, constraints on modelled variables may be imposed during training using an appropriate loss function or by using an acquisition function that increases the likeliness of selecting values that obey the constraints.

Another objective relating to the powertrain may involve achieving a high efficiency 346 of the powertrain 102 for given values of the input variables 338 under the condition that the generated torque 342 is close to the target torque 332. In this setting, it may be possible to directly model the efficiency 346 as a function of the input variables 338. Such an approach may involve determining a model which accounts for the potentially heteroskedastic noise in efficiency 338 over the input space. An alternative approach may be adopted, wherein the efficiency 346 of the powertrain 102 may be determined by a ratio of the generated torque 342 and the DC current 344. For example, in an accelerative mode of operation, the generated torque 342 may be considered as an output and the DC current 344 as an input of the powertrain 102. As a result, the efficiency 346 of the electric vehicle may be related to the ratio of the generated torque 342 to the DC current 344. Similarly, in a regenerative braking mode of operation, the ratio determining the efficiency 346 may be inverted. In these cases, the efficiency 346 may be modelled in dependence on models for the generated torque 342 and the DC current 344, wherein the generated torque 342 is constrained to be equal or near-equal to the target torque 332 specified by the driving inputs 114. This approach may obviate the need for modelling heteroskedastic noise since the constitutive models (for generated torque and DC current) tend to exhibit homoscedastic noise over the input space. As a result, a model for the generated torque 342 over the input space may be useful with regard to both objectives described above. In either of these cases, the torque constraint may be incorporated into the objective function, for example by penalising the objective function in dependence on a probability or likeliness that the torque constraint is not satisfied, as predicted by a GP model for the generated torque (as described below).

Measured values of variables of the powertrain 102 (as shown in FIG. 3, for example) tend to exhibit statistical variations due to factors not captured by the context and decision variables. For example, the generated torque 342 may assume a range of values for a single point in the input space. Similarly, the performance characteristics 340 as well as each of the context variables 322 and the decision variables 324 themselves exhibit statistical variations. Due to this underlying statistical variability, deterministic models may be unable to adequately capture the dependence of performance characteristics such as generated torque on the context and decision variables. According to the present disclosure, the performance characteristic is modelled instead as a random variable whose statistics are governed by an underlying probabilistic model, such that any statistical variability is captured by a variance or higher-order statistical moment described by the model. Suitable probabilistic models may be developed by providing statistically relevant values of the input variables and subsequently fitting a model to the available data. As mentioned above, it is an objective of the present disclosure to develop an accurate probabilistic model of the generated torque 342 over the input space to calibrate the ECU 110.

Returning to FIG. 2, the data processing system 248 includes a module for obtaining or collecting relevant measurements. Data from measurements may correspond to values of the set of context variables, the set of decision variables, and any relevant performance characteristics. In order to guide the experimentation on the test bench 216, the data processing system 248 includes a number of functional components, any of which may be implemented in hardware, software, or a combination of both. In particular, the data processing system 248 includes a model training component 250, which is configured to train one or more probabilistic models for predicting the dependence of performance characteristics of the powertrain 102 on the context variables and decision variables, based on measurements of the performance characteristics obtained from the test bench sensors 220. Values of the context variables, decision variables, and/or powertrain performance characteristics may be pre-processed, combined, or otherwise adjusted before being processed by the model training component 250. For example, it may be desirable to normalise at least some of the variables and/or to filter the data prior to training.

A number of modelling approaches may be availed for use in training a probabilistic model for the generated torque or other performance characteristics. For example, the probabilistic model may be a Gaussian Process (GP) model, a deep GP model or variant thereof. GP models may be an appropriate choice for modelling when limited data is available for training. In the context of small datasets, exact inference may be conducted using Gaussian Process Regression (GPR) models. For relatively larger datasets, approximate inference using alternative GP techniques such as Sparse Gaussian Process Regression (SGPR) that involve compression of data into a manageable number of pseudo-data points may be applicable. Sparse Variational Gaussian Process (SVGP) models, which rely on inducing points to make training data manageable and also extend in applicability to models with non-Gaussian noise, may be advantageous in some contexts. Further, nested Gaussian Processes offer an alternative to the variational inference adopted by SVGP models. Apart from GP models, various classes of neural networks such as Bayesian Neural Networks or variants thereof may be adopted for the purpose of modelling.

A GP model has the advantage that the marginal distribution of any finite number of variables of a GP is a multivariate Gaussian distribution. As a result, Bayesian Optimisation can be performed in a framework involving a Gaussian Process as a prior, whereby acquisition functions guide selection of the most informative training datapoints resulting in efficient training of the GP models. Compared with other types of machine learning models, GP models perform well in the sparse data regime, meaning that GP models can be particularly advantageous in situations where data collection is inherently difficult or expensive.

Due to the Gaussian property of a GP, any GP model may be described completely by their second-order statistics. A GP model for a quantity includes two functions: (1) a mean function that models the variation of an expected value of the quantity over an input space and (2) a covariance function or kernel that models the covariance of the quantity for pairs of points in the input space. The predictive ability of a GP model can vary dramatically depending on whether the prior mean and covariance functions of the model offer a suitable representation of the particular dataset on which the GP model is trained. Encoding appropriate prior beliefs in a GP model typically involve prescribing the mean function. In the present example of training GP models for the generated torque, a prior belief may be encoded by prescribing a physical equation derived for the torque generated by a PMSM. In a PMSM, the dependence of the generated torque on the AC amplitude and the AC advance angle at constant electric motor temperature is given as follows:

$$TQ = {C}_{0} + {C}_{1} \cdot Ia \cdot cos ( β ) + {C}_{2} \cdot {Ia}^{2} \cdot sin ( 2 β )$$

where TQ is the predicted value of the generated torque, Ia stands for the AC amplitude and B denotes the AC advance angle. In the equation above, the constant C₀ represents frictional losses due to resistance, for example. The coefficients C₁ and C₂ are functions of physical quantities governing the operation of the electric motor 108. For example, C₁ and C₂ may be dependent on the flux linkage of the permanent magnet of the rotor, the inductance of the stator, and the number of motor pole pairs. These coefficients may be expected to have statistical variations over the input space. For a GP model defined using a mean function according to the equation above, the role of the covariance function is to quantify departures from the equation. Training a GP model for the generated torque in this manner results in quantification of the coefficients such as C₁ and C₂ for a given set of measurements obtained from the test bench 216. Effectively, training GP models encoding the prior belief in the mean function leads to knowledge of coefficients in prescribed mean equations that fit the data. A significant drawback of this approach is that training leads to prediction of precise values of the coefficients rather modelling of their statistical variation and uncertainty. Furthermore, extending the model to include dependence on other variables hinges on the known equation for the generated torque capturing a dependence on such variables. For example, the equation above is a theoretical equation applicable under the condition of constant temperature. It may be surmised that the generated torque varies with temperature, particularly at high temperatures, but a concrete mathematical description of such a dependence may be unavailable and require scientific research and experimentation. A GP model for the generated torque prescribed with a mean based on the equation above may be unable to capture a dependence on the temperature on its own.

As an alternative to the approach described above, the present disclosure instead advocates encoding domain specific knowledge in the covariance function of the GP model. Covariance functions for GP models are typically prescribed in terms of standard functions such as exponential, sinusoidal, or polynomial functions. In this example, the physical equation known a priori describes the dependence of the generated torque in terms of the AC amplitude as a quadratic polynomial, and the dependence on the AC advance angle in terms of standard sinusoidal functions. It is therefore possible to prescribe the GP model for the generated torque with a covariance function including sinusoidal dependence on separations in terms of AC advance angle, rather than individual values of the same. Thus, the covariance function (or the kernel) may be written as:

$$K = {K}_{0} + {K}_{1} \cdot Ia \cdot {K}_{{C}_{1}} ( 1 ) + {K}_{2} \cdot {Ia}^{2} \cdot {K}_{{C}_{2}} ( 1 / 2 ) + {K}_{exp} \cdot Ia$$

where K₀ is a constant kernel, K₁ and K₂ may be linear kernels or other appropriate coefficient kernels, and Kₑₓₚ is the exponential kernel which incorporates any smooth behaviour in the dependence on the AC amplitude. The sinusoidal dependence of the generated torque on the AC advance angle is incorporated via the sinusoidal kernel functions K_{C}_{₁} and K_{C}_{₂}. In the example shown, the linear and quadratic terms in the AC amplitude are retained. In this example, the covariance function depends on a separation l between points along the dimension of a decision variable, namely the AC advance angle, according to a domain-specific equation known a priori. Additionally, the covariance function in this example has a dependence on the AC amplitude included in the coefficients of the kernels K_{C}_{₁}, K_{C}_{₂}, and Kₑₓₚ. In other examples, the functional dependence may involve other variables or equations. For example, the covariance function may additionally have a specified dependence on the motor speed and/or the direct voltage. When the alternating current is represented or parametrised using variables other than the amplitude and advance angle (for example, orthogonal components of an alternating current vector), the covariance function may instead depend on those variables in a manner that corresponds to a specified physical relationship between a performance characteristic and those variables. Such variables may additionally or alternatively be included in the coefficients of one or more kernel components forming the covariance function. An advantage of encoding the sinusoidal dependence into the covariance function is that uncertainties and statistical variations of the coefficients in the equation are retained in the trained GP model. This is because training involves marginalisation over the coefficients involved in the physical equation, rather than identification of the coefficients. A further advantage of the approach described above is that it allows inclusion of dependence on variables other than those already included in the domain specific equation. For example, a dependence of the generated torque on the temperature may be included in the formulation above. One method of including such a dependence is to add terms in the covariance function given above that depend on the electric motor temperature. Alternatively, a separate covariance function may be defined to capture the dependence of the generated torque on the electric motor temperature. For instance, a linear kernel with a trainable offset may be used to describe a temperature kernel, which may be multiplied with the covariance function defined above for the kernel at constant temperature. Such a formulation may represent the assumption that the electric motor temperature affects the generated torque by a fractional amount rather than additive amount. The approach adopted here including the resulting equations for the kernel are found to be well-suited to a powertrain including a PMSM. Other forms of kernel may also be used without departing from the scope of the present disclosure, for example to reflect the physics of a different type of powertrain. The equation prescribed by the physics may include further variables and may not necessarily prescribe the functional dependence of the torque on decision variables only. Furthermore, it is to be understood that the approach adopted above, namely that of prescribing the covariance function rather than mean function with a known equation, is widely applicable. For example, it may be applied to improve GP models for physical quantities of other powertrains, including hybrid vehicles, or to contexts beyond vehicle powertrains.

The system 200 is configured for training a GP model of the type discussed above by systematically obtaining data from the test bench 216. The data processing system 248 includes an input selection component 252 arranged to determine locations in the input space having dimensions respectively corresponding to the various context variables and decision variables included in the input space. The input selection component 252 has the task of selecting input locations which balance exploration (to learn about the effect of the parameters/variables throughout the parameter/variable space) and exploitation (focusing on combinations of parameter/variable values likely to yield favourable performance whilst also obeying constraints). The number of data points that can viably be collected may be relatively low, leading to high levels of uncertainty about the effects of the individual parameters on the performance characteristics, particularly in the early stages of experimentation. In accordance with the present disclosure, the input selection component 252 is arranged to determine input locations using Bayesian optimisation, based on an acquisition function which evaluates outputs of the GP model(s) at candidate sets of locations in the input space. The acquisition function may take the form of an upper confidence bound, maximum probability of improvement, expected improvement or augmented expected improvement. The purpose of the acquisition function is to evaluate the outputs of the GP models in a way which addresses the so-called exploration/exploitation dilemma, enabling close-to-optimal ECU mappings to be determined in an efficient manner. The acquisition function may also be penalised in dependence on a probability that one or more constraints on the variables relevant to the powertrain 102 are violated for at least a subset of points in the input space.

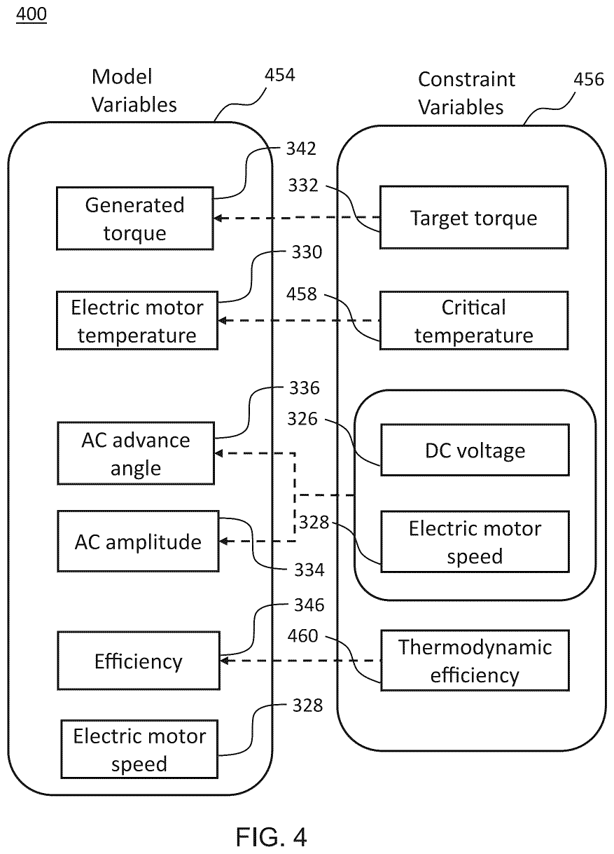

Accurate modelling of a performance characteristic 340, such as the generated torque, may demand adherence to a number of constraints during the calibration procedure. FIG. 4 shows model variables 454 and their respective constraint variables 456 used in the procedure for calibrating an ECU 110. Model variables 454 may be any of the variables involved in the modelling of a performance characteristic 340 as discussed in FIG. 3. Constraint variables 456 may include variables whose values impose a constraint on the values achievable by the model variables 454. In some examples, the performance characteristic 340 being modelled may be imposed by a physical constraint from a constraint variable 456 as part of the heuristic adopted for achieving suitable values of the objective function. For example, as discussed above, the objective of finding low values of the AC amplitude 334 for a given value of target torque 332 may rely on constraining modelled values of generated torque 342 to be approximately equal to the specified values of target torque 336. In order to enforce such a constraint, a tolerance parameter may be defined to indicate the maximum allowed deviation between the generated torque 342 predicted by the trained model and the target torque 332 as specified by the driving inputs 114. Alternatively, a tolerance fraction may be specified with respect to either of the two torque quantities. A combination of the two tolerance measures may also be adopted, as for example:

$$ΔTQ < max ( {Δ}_{max} , {π}_{max} \times TTQ )$$

where ΔTQ≡|TQ−TTQ| is an observed deviation between the predicted value of TQ, the generated torque 342, and the specified value of TTQ, the target torque 332. Values of the tolerance parameter Δₘₐₓ and the tolerance fraction πₘₐₓ may be specified to indicate the maximum allowed deviation between TQ and TTQ. The constraint may be imposed on a pointwise basis in the input space, filtering out points where the model being trained does not satisfy the constraint. Alternatively, the constraint may be extended on the training procedure itself by including a constraint formulation in the acquisition function that governs choice of training query points. For example, a dependence on the probability of the observed deviation exceeding a threshold value may be included in probability values estimated by the acquisition function. Such dependences may be combined with any of the forms of acquisition functions described above, such as expected improvement.

Some constraints on model variables 454 may help eliminate regions of parameter space corresponding to unsafe operation of the powertrain 102. Enforcing such constraints may simultaneously reduce the size of training space. For example, the temperature 330 may be constrained to remain below a critical temperature 458 corresponding to a maximum operating temperature considered safe for the operation of the motor 108. In order to enforce this constraint, the electric motor 108 may be manually or automatically switched off for a certain period of time until the temperature 330 has reduced to a safe level. Probabilistic models being trained may as a result be able to avoid having to model large regions of the input space 338 in this manner.

Constraints may further be applied with the express aim of reducing the size of exploration space. For example, it may be known that values of the AC advance angle 336 and the AC amplitude 334 are inter-related mathematically to values of DC voltage 326 and electric motor speed 328. Such a voltage constraint may arise in principle because (a) a finite voltage may be available to be applied to the stator from the battery 104, and (b) a significant voltage on the stator, known as the back EMF, may be induced by the magnet in the electric motor 108 at higher motor speeds 328. In this context, it may be possible to derive a model of the voltage constraint to assist in determining which regions of the space correspond to feasible states of operation. Such mathematical relationships may be derived based on physical principles and may be used to guide the selection and training of an appropriate GP model for the generated torque 342 from the resulting constrained input space. For example, the equation governing the DC voltage 326 in dependence on the AC advance angle 336 and the AC amplitude 334 may be prescribed as the mean function of a probabilistic model configured to predict voltage values corresponding to values of the AC amplitude 334 and the AC advance angle 336. The probabilistic model may be a GP model or an appropriate probabilistic model. Voltage values predicted by the probabilistic model may be compared with a utilisation value, which may be defined, for example, as a fraction of the DC voltage 326. Subsequently, only values of AC advance angle 336 and AC amplitude 334 corresponding to the predicted voltage being less than the utilisation value may be considered as being feasible. Since the AC advance angle 336 and the AC amplitude 334 are included in the set of decision variables 224, constraining these variables using the probabilistic voltage constraint model described thus far reduces the volume of the decision space to be explored or queried for training. The reduced volume corresponds to a feasible space which includes only the values of decision variables which are physically realisable. Alternatively, rather than implement a trainable probabilistic model such as a GP model, it may also be possible to adopt a simpler deterministic model to determine the feasible region of the search space. For example, the deterministic model may be derived based on a physically motivated equation relating the variables mathematically as in the description above.

In addition to the examples above, constraints may also be useful for ensuring that the probabilistic model upholds fundamental principles of physics. For example, the thermodynamic efficiency 460 of a physical system cannot exceed the value of unity. In order to ensure that such physical principles are not violated in the trained model, the probabilistic model for efficiency 342 may be constrained by this thermodynamic limitation. Several techniques may be applied to enforce such constraints on the efficiency 346. A method of imposing the constraint discussed here is to filter the distribution included in the probabilistic model for efficiency to retain those samples that correspond to efficiency lying between zero and one.

The method of training described above results in a relatively more accurate GP model for the generated torque in the input space. When the objective is a maximisation of the efficiency, it is important to estimate a probabilistic model for the efficiency in dependence on the variables included in the input space. In the framework of second-order statistics, estimating the probabilistic model may require estimation of a mean and variance of the efficiency. As discussed before, the efficiency of an electric motor 108 may be determined in direct proportionality to the ratio of two observables. In a drive regime, the ratio may be a ratio of the generated torque and the DC current. In the regenerative braking regime, the inverse ratio may be appropriate. One approach to estimating the probabilistic model for efficiency is to derive a model based on the ratio of probabilistic models for the DC current and the generated torque. The discussion thus far has explained methods of determining a GP model for the generated torque, where the covariance function rather than the mean function was prescribed for improved modelling of the statistical uncertainties in the prescriptive equation of the generated torque. The DC current, however, may be estimated using a GP model by initialising the mean and covariance functions without recourse to a prescriptive equation. Given the resulting Gaussian distributions for DC current and generated torque, the posterior probabilistic model for the efficiency may be estimated as the ratio of two Gaussian distributions. Though this may immediately allow estimation of the mean and variance of the efficiency, it may not obey the thermodynamic constraint on the efficiency to be between 0 and 1. As a consequence, samples obtained from the ratio distribution may be filtered to retain those that obey the thermodynamic constraint. An alternative approach may involve sampling the individual Gaussian distributions for the generated torque and the DC current prior to computing the ratio for estimating the efficiency. As discussed above, a thermodynamic constraint may subsequently be applied on samples of the resulting probabilistic model for the efficiency. An alternative approach may be followed wherein the probabilistic model for the efficiency may satisfy the thermodynamic constraint by definition. Such a probabilistic model may be constrained to output samples lying between 0 and 1, thereby precluding the need to filter the samples after having estimated the posterior distribution. In one such approach, the posterior distribution for efficiency may be derived based on a prior for efficiency that is constrained to lie between 0 and 1. The likelihood of the efficiency may be derived under the assumption that the generated torque and the DC current are related linearly by virtue of the formula for efficiency. The prior and the likelihood may then be used together to estimate the posterior distribution for efficiency. In this manner, an appropriately defined prior and a likelihood may be used to derive a posterior that automatically satisfies the thermodynamic constraint, obviating the need to filter the samples of the distribution any further.

Returning to FIG. 2, the input selection component 252 may be configured to determine sets of locations having a predetermined configuration relative to one another in the input space. For example, candidate sets of locations may only be considered for which the locations have a specified relationship to one another (though the absolute locations will vary between candidate sets). By imposing a predetermined relative configuration on the locations, the dimensionality of the search space is effectively reduced, which is beneficial for reducing the duration of each iteration of Bayesian optimisation, and thereby the associated computational cost.

In the context of the PMSM described above, the input space is a five-dimensional space that includes the AC advance angle, the electric motor speed, the DC voltage and the AC amplitude. As indicated previously, individual motor measurements are not exact and instead are associated with uncertainties due to, for example, a combination of rippling, observation error and measurement error. Therefore, data collected at any given point in the input space may instead correspond to a set of measurements to help establish steady-state behaviour before collecting data and to help collect statistically meaningful values when defining the steady-state behaviour. When a sufficient volume of measurements has been collected, the data processing system 248 may generate ECU calibration data for calibrating the ECU 110. For this purpose, the data processing system 248 includes a calibration component 274, which is arranged to generate ECU calibration data based on values of the powertrain performance characteristics predicted by the trained GP model. For a given combination of context variables, the calibration component 274 may be arranged to numerically solve an optimisation problem to determine values of the decision variables for which the probabilistic model predicts an optimum value of a given performance characteristic (such as generated torque or efficiency) whilst also having a high probability of satisfying the given set of constraints. The resulting mappings from context variables to decision variables may then be stored as ECU calibration data. The ECU calibration data represents a mapping of values in the form of a lookup table or other type of data structure. The ECU 110 may be configured to use the lookup table directly to map the set of context variables to the set of decision variables (for example by selecting the nearest entry in the lookup table for a given value of the context variables) in the input space, or may be configured to interpolate between values of the context variables and/or decision variables to determine a mapping for any set of values of the context variables.

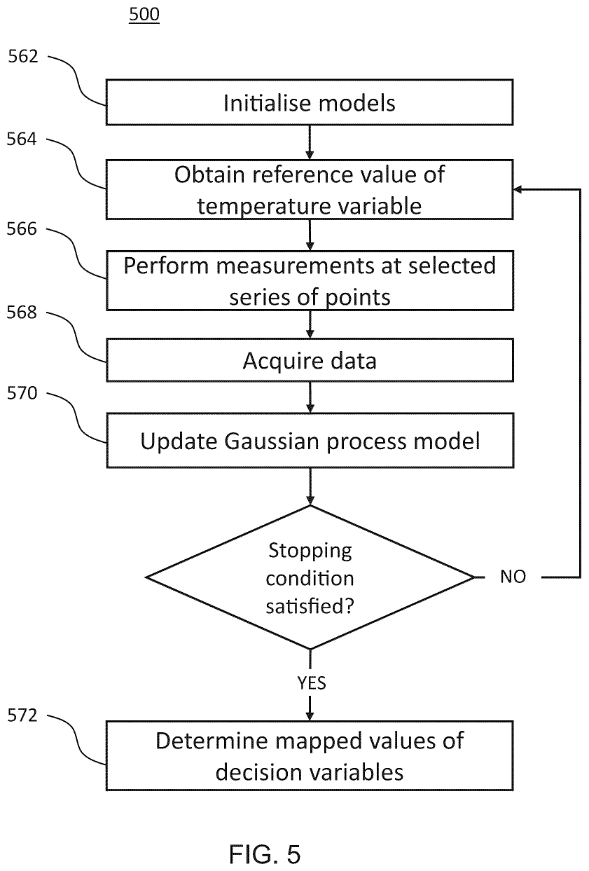

FIG. 5 shows an example method of training a GP model to predict outputs of a powertrain performance characteristic. The method 500 includes initialising one or more GP models at step 562. The one or more GP models may include a GP model for the torque of the powertrain, along with optionally a further GP model for use in calculating the objective function. Initialising the one or more GP models includes determining initial values for trainable parameters of the one or more GP models, including for example hyperparameters and variational parameters. The initial values may be determined randomly or by any other suitable method, for example independently of any empirical data or using historic data. The initialising at 562 may further include performing an initial training phase in which an initial dataset is collected from a test bench 216 independently of any Bayesian optimisation step and used to train one or more GP models in order to seed the Bayesian optimisation process. The initial dataset may include measurements of the powertrain performance characteristics at a relatively small number of sets of input locations (for example, ten, fifty or one hundred sets of input locations).

Typical methods of efficient Bayesian Optimisation attempt to reduce the number of required iterations. The number of iterations required for the model(s) to converge, or to satisfy any other prescribed stopping condition, for example, can be an approximate measure of the expense involved in training the GP model. However, iteration count is not a direct measure of the time elapsed during training. In some cases, it is more important to make the overall training more efficient in terms of “time elapsed” rather than “iterations required” for training, for example due to the need to reduce costs training on the test bench 216. These two qualities of a Bayesian Optimisation procedure are different particularly when the time taken to transition between successive iterations is large and/or depends upon the respective chosen locations in the input space. For example, time elapsed between iterations typically depends on two factors: (1) the computational time taken by the input selection module 252 to propose a new query point or set of query points, and (2) the time required for the electric motor 108 to reach an appropriate operational state corresponding to the proposed query point or set of query points. Depending on the parameters being varied between successive iterations, the time required for the motor to transition can prove to be a bottleneck.

In the example shown in FIG. 3, the decision variables AC amplitude and AC advance angle do not necessitate large transition times of the electric motor 108. Though in some cases, the rapid transitions in these current variables can lead to undesirable transient effects; it is possible to limit such rapid changes by prolonging the time budgeted for transitions between values of current variables. Setting aside the transient effects, transitions in the decision variables do not in and of themselves contribute significantly to the training time. Exploration of the search space may nevertheless be made efficient by adopting a sweep strategy that involves collecting data at points having a pre-determined relative configuration in the decision space. The pre-determined series of points may therefore be represented by a space with significantly reduced dimensionality than the entire decision space, thereby reducing the time required to acquire data at each point in the overall search space. Values of the acquisition function corresponding to points in the sweep may be summed to determine a single value to be used in comparing candidates sweeps across the decision variables. Alternatively, other methods of combining values of the acquisition function for points in the sweep may be adopted.

The simplest “sweep” strategy is to employ no sweep across the decision space, meaning that each Bayesian optimisation iteration results in a single query point. An advantage of this approach is that the measurements may be more stable with lower noise properties because the motor can achieve a steady state for a long period of time. This may partially result in a reduction in the time required to train the probabilistic models since the total number of datapoints is greatly reduced. Regardless, the key drawbacks of the method include (a) sparse exploration of the input space, thereby potentially harming performance, and (b) prolonged periods of time spent in certain regions of the input space, leading to potential heating of the motor.

An alternative sweep strategy involves reducing the dimensionality of the decision space by pre-determining a relative configuration of points in one dimension of the decision space. For example, a sweep may be conducted in the dimension corresponding to the AC amplitude by pre-determining the values of AC amplitude for which data may be collected during a given iteration, for example to cover the entire range of possible values for the AC amplitude with a predetermined spacing. This alleviates the requirement of assessing values of this variable and thereby reduces the dimensionality of the search space by one. As a consequence, the one-dimensional sweep strategy may result in significant reduction of the overall training time.

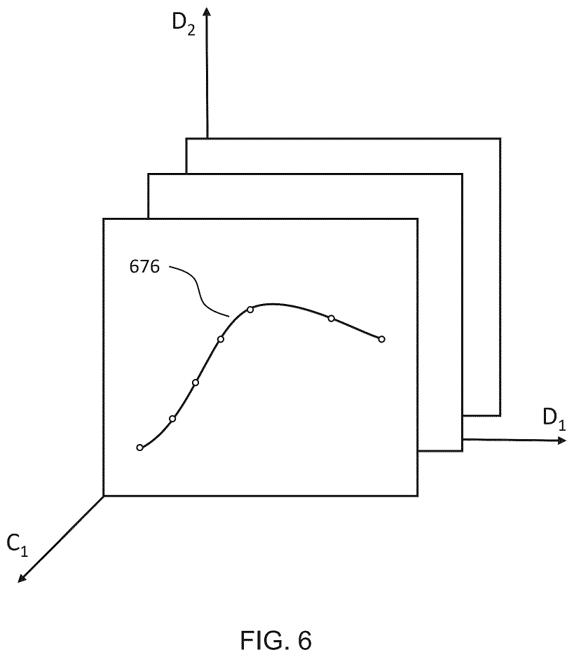

The one-dimensional sweep strategy can be extended to multiple dimensions of the decision space. For example, a sweep may be performed over a trajectory corresponding to an estimated theoretical functional form of the profile optimum in the entire decision space, i.e. including values of both decision variables. FIG. 6 shows an example trajectory for collecting query points in decision space for training a GP model. In the figure, slices of a part of the search space corresponding to different values of a context variable C₁. Each two-dimensional slice corresponds to a decision space, governed by decision variables D₁ and D₂ that correspond to the AC amplitude and the AC advance angle. In each slice, the equation governing the optimal choice of current given by theoretical first principles may form a theoretical profile optimum trajectory 676. The sweep strategy may therefore involve scanning points along this theoretical profile optimum trajectory 676. The functional form of the theoretical profile optimum may be derivable based on the principles of operation of the electric motor 108, and may depend upon the particular objective function under consideration. Such sweep strategies alleviate the computational expensive of data acquisition over the decision space entirely. In a similar manner, sweep strategies may apply to different combinations of the input variables depending on the specifics of the problem.

Once a sweep strategy has been specified, data may be acquired for training at each point corresponding to values of any remaining variables in the search space. In this example, a sweep may be predetermined in the decision space as described above, leaving values of the context variables to be determined. In this regard, the electric motor temperature can be a challenging parameter to control, because heating of the electric motor 108 occurs throughout its operation, and thus the temperature increases “passively” in the absence of a known desired change in the temperature. Moreover, changes in the motor temperature over successive iterations are sensitive to the transitions in the other variables between the iterations. Still further, reducing the temperature of the electric motor 108 is a slow process governed by natural cooling mechanisms. Reducing the temperature may also impose constraints on attainable values of the AC amplitude because the presence of a current may lead to resistive heating, acting against the desired transition in temperature. Typically, there must be either no current or a very small current flowing through the stator, i.e. a small AC amplitude, to allow the electric motor 108 to cool down to a lower temperature.

In summary, the five dimensions corresponding to the variables in the input space shown in FIG. 3 include: exploration of two cheap dimensions (AC amplitude and AC advance angle), followed by exploration of the relatively expensive DC voltage and the electric motor speed dimensions, and finally extremely expensive exploration relying on transitions in the electric motor temperature. Upon specifying the sweep in the decision space (in the “cheap” dimensions), a baseline data acquisition strategy may involve determining the three remaining context variables using Bayesian Optimisation. Though it may be conceivable that optimisation conducted in this manner converges in a fewer number of iterations, it may actually be lengthier and more expensive due to the potentially dramatic transitions in temperature across the iterations. It is therefore advantageous to diminish the total temperature change over training (while still adequately covering values of variables in the input space) to increase the speed of optimisation.

One approach for prioritising the relatively cheaper transitions is to account for the time required to transition between successive temperature states in the acquisition function that determines the next query point in the search space. It is possible to account for this time of temperature transition by modelling the appropriate cooling laws for the electric motor and incorporating it as a likeliness for the next query point to be optimal with respect to the acquisition. An alternative approach to avoid wasting valuable time on the test bench 216 is to forego active control of the temperature variable. Instead, data points corresponding to different temperature values may be accessed as a consequence of the transition of the motor 108 between states corresponding to the remaining input variables. For example, in this approach, the temperature may be allowed to rise naturally during the course of the operation of the motor 108 until a predetermined critical temperature 458 is attained (shown as a constraint in FIG. 4). Bayesian Optimisation may be performed at each step, where the query point or set of query points for a successive iteration is determined in correspondence with the temperature during a preceding iteration. In this manner, the GP model being trained is able to account for the historical temperature measurements, which is important for modelling the generated torque, yet the temperature is never controlled directly. After reaching the predetermined value of critical temperature 458, the motor 108 may be shut for a prolonged period until a suitably low temperature value (for instance, close to the room temperature) is attained. This reduces the total number of transitions between temperature values attained by the motor, thereby drastically reducing the time spent training on the bench. If the calibration map found after one of these heating cooling cycles proves to be inadequate, then the process is repeated. This strategy for Bayesian Optimisation, wherein direct control one of the variables (the temperature) is relinquished, may be referred to as a passive control strategy.

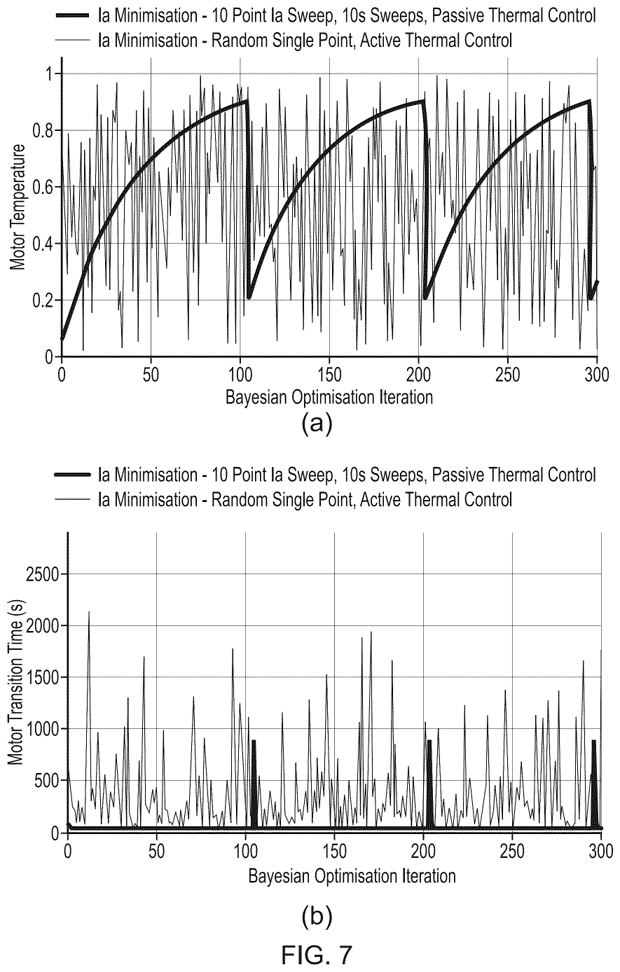

FIG. 7 compares the performance of example methods of Bayesian Optimisation used for training a GP model. In active thermal control, the temperature of the electric motor 108 is changed actively as a result of the outputs of the acquisition function. In passive temperature control, temperature is allowed to rise naturally during the operation of the electric motor 108 instead. The passive strategy results in gradual warming of the motor as the optimisation progresses, whereas the active strategy requires erratic warming and cooling of the electric motor 108 as seen in FIG. 7 (a). As a consequence of the erratic heating of the electric motor 108 in the active strategy, it results in significantly larger transition times between iterations of the Bayesian Optimisation procedure. Instead, the passive temperature control strategy requires infrequent transitions in temperature as seen in FIG. 7 (b), thereby reducing the overall training time of the test bench 216. Passive temperature control gives a dramatic speed-up in performance over an active controller despite the potential risk that the exploration of the temperature dimension in the input space is uneven. A further advantage of adopting a passive temperature control strategy over approaches that account for the transition time in the acquisition function, for example, is that no access to a thermal model is required for estimating the transition time between temperature states. The burden of computation (and the resulting computation time) on the data processing system 248 is thereby further reduced. Moreover, the requirement of developing such models using pre-calibration simulations and testing is also alleviated. These advantages greatly improve the applicability of the passive temperature control strategy for acquiring data as it can be applied to new motors without requiring a temperature model specific to that motor.

In some cases, it may prove infeasible to attain the critical temperature 458 solely using passive temperature control. In such instances where the entire practically valuable range of temperature is not accessible via passive temperature control, it is possible to deliberate an appropriate increase in the temperature of motor by increasing the temperature of oil circulating in the motor. Upon achieving the required higher values of temperature of the motor, or during the operation of the motor otherwise, the oil temperature may be reduced to a minimal level to regulate any undesirable rise in temperature, and to allow the passive temperature control strategy to operate and explore values of temperature within a feasible temperature band. For some motors, it may be advantageous to slowly increase the temperature of the oil going into the engine to allow full exploration of the temperature range. The oil temperature may be set to follow an automatic slowly increasing schedule, or it may be possible to warn or trigger a manual increase once temperature stagnation is detected. Setting aside the relatively minor increase in the complexity of exploration in such circumstances, the passive temperature control strategy lends a value of the temperature variable for acquisition as a result of the natural operation of the motor. Returning to FIG. 5, the measured value of temperature during an iteration of Bayesian Optimisation may be used as a reference value, in 564, to specify the corresponding coordinate of the query point in the input space. Moreover, since transitions in the decision variables are relatively fast, changes in the temperature over a single sweep of the decision variables may be assumed to be relatively insignificant.

The passive temperature control strategy, particularly when combined with a sweep strategy in the decision space, may result in a drastic reduction of dimensionality of the overall search space. Furthermore, the performance of optimisation is particularly enhanced when passive temperature control is used in tandem with the specification of the covariance function as described above. This enhanced performance under passive temperature control in this setting may be caused by the temperature dependence on the torque encoded in the covariance function.

Once the reference value of the temperature variable has been specified, values of the remaining context variables may be determined to completely specify the query points in the search space. In contrast with sweeps across values of the decision variables, during a transition between values of either or both of the DC voltage and the electric motor speed, the electric motor temperature is expected to change significantly, meaning that a change of values in these dimensions cannot be achieved without a corresponding change to the electric motor temperature. Therefore, it may be appropriate to consider individual values of each of these context variables at each Bayesian optimisation iteration. Values of these context variables may for example be obtained using standard approaches of Bayesian Optimisation, i.e. based on values of the acquisition function. Alternatively, approaches that pre-determine one or more values of the context variables may be adopted to reduce the dimensionality of the overall optimisation problem. For example, in two- and three-dimensions it may be possible to define a space-filling curve—a parametric one-dimensional curve with the property that it fills a higher-dimensional space on iterative application.

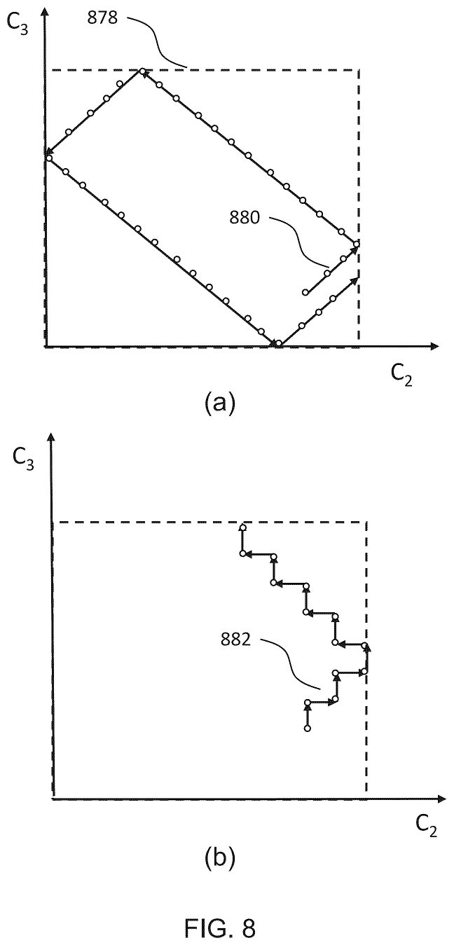

FIG. 8 shows example configurations of successive sets of query points in the context space for the purpose of model training. A strategy termed the “pong” strategy is shown in FIG. 8(a), wherein parameters of the space-filling curve are based on the principles of a frictionless ball bouncing in a bounded space. To trace the “pong” trajectory in the search space, one may start with a random initial point within the search space and prescribe a velocity to determine the rate of change of the point in the space. Subsequently, the trajectory of the point may be followed by updating the value of the position by integrating the velocity as a function of time, taking into account reflections at boundaries of the search domain. The locations of the point in the search space may be sampled at regular time intervals to get a smooth space-filling curve. Query points for Bayesian Optimisation may be determined in correspondence with the points along the resulting space-filling curve. FIG. 8.(a) illustrates this sweep strategy being adopted in a two-dimensional context space within the search space, determined by context variables C₁ and C₂ within a bounded domain 878. Although the “pong” strategy results in a space-filling 880 that can be traced to collect query points for training, diagonal movements across some of the context variables can be expensive. For example, if the context variables defining the context space are electric motor speed and the DC voltage, then diagonal movements in the domain involve simultaneously changing the two variables and this can be expensive as the transition costs in each of these variables tend to be additive. Due to the reasons outlined above, it can be favourable to replace the diagonal movement across the context space as traced by a “pong” strategy by breaking down the transitions along the diagonals of the space-filling curve. Each of the transitions can be made to align with one or the other context variable axis, resulting in a trajectory 882 covered by the point having a profile reminiscent of the popular mobile phone game “snake”. It is observed that such a “snake” strategy for sweeping through context space provides an additional improvement over “pong”, achieving similar regret performance whilst incurring lower transition costs. In this manner, the entire search space may be explored quickly by relying on a combination of the (a) sweep strategy, (b) passive temperature and (c) context space movement. The resulting efficient methods of training probabilistic models for, the calibration procedure is made more practicable.

Returning to FIG. 5, the method 500 continues with performing measurements of the powertrain performance characteristics and the values of variables included in the input space at 566. To obtain the measurements, the powertrain is operated on the test bench 216 with values of the context and decision variables set to values according to the determined set of locations in the input space. For each location, values of the powertrain performance characteristics such as the generated torque or the DC current are measured empirically using test bench sensors 220. For each measurement, a data point is generated having an input portion representing the values of the context variables and decision variables, and an output portion representing the measured values of the powertrain performance characteristics. The obtaining of measurements for a given set of input locations may be performed automatically or with some level of human input. Furthermore, as explained above, the measurements may be performed at a far greater density of input locations than is determined at 566 to ensure fine-grained coverage of the relevant region of the input space, and at locations only approximately corresponding to those determined at 566. In cases where one or more constraints are found to be violated at a given input location, the taking of measurements may cease at that input location, or such points in the input space may be avoided altogether. Before proceeding to the next step, the measurements obtained at 566, along with the corresponding values of the context and decision variables, may be pre-processed, combined, normalised or otherwise altered. In particular, measured values of one or more performance characteristics may be detrended with respect to one or more context variables and/or decision variables. At step 568, acquired data corresponding to the processed measurements is collated.

The method 500 proceeds with updating, at 570, the one or more GP models using the acquired data obtained at 568. In particular, values of the trainable parameters for each of the one or more of the GP models, including hyperparameters and variational parameters of the GP models and any auxiliary GPs, may be updated using gradient-based optimisation with respect a maximum a posteriori or maximum likelihood objective function. Updating the GP models may include retraining the GP models from scratch (for example using the initialisation method described above) using all of the data collected up to and including the current iteration. Alternatively, values of certain parameters of the GP models, such as kernel hyperparameters and mean functions, may be maintained or copied from the previous iteration (or from the initialisation step 562), which may reduce the number of gradient steps required at each iteration. Values of the variational parameters may also be determined at each iteration in dependence on values of the variational parameters from the previous iterations, though it may not be possible to copy these values over directly due to the inducing input locations changing between iteration.

The steps 564 through to 570 continue iteratively until a predetermined stopping condition is satisfied, with new measurements being collected and the GP models being updated at each iteration. The stopping condition may for example include one or more convergence criteria being satisfied, one or more powertrain performance criteria being satisfied, or a predetermined number of iterations having taken place. At a given iteration, an estimated profile optimum is available to the extent that for a given set of values of the context variables, a set of estimated optimal values of the decision variables can be determined using gradient-based optimisation. A stopping condition may also include a predefined amount of time available of the test bench 216 expiring. The stopping condition may be dependent on evaluations of the GP models at the estimated profile optimum. For example, the stopping condition may be dependent on a metric comparing a deviation between the determined values of the decision variables (or the corresponding value of the profile optimum) at a given iteration with the values determined at a previous iteration. The stopping condition may be dependent on this deviation falling below a given threshold, indicating that the profile optimum has converged. Examples of suitable metrics include root mean squared difference or mean absolute difference. Alternatively, or additionally, the stopping condition may be dependent on a mean variance of one, some, or all of the GP models at the estimated profile optimum dropping below a given threshold. In this way, the uncertainty estimates built into the GP models can be used to self-assess the quality of the profile optimum estimate at each iteration.

When the stopping condition is satisfied, the method 500 concludes, at 572, by generating ECU calibration data for mapping values of the one or more context variables to values of the one or more decision variables. The ECU calibration data may be in the form of a lookup table or equivalent data structure. Generating the ECU calibration data may involve, for combinations of context variables covering the entire permissible domain of context variables at a sufficiently high resolution, performing gradient-based optimisation using the trained GP model(s) to estimate suitable values of the decision variables, and storing the resulting mappings. Suitable values of the decision variables may be determined using the probability distributions generated by the GP models, for example based on a maximum expected value of the objective function predicted by the models, or any other suitable function of the outputs, for example depending on expectation values and/or quantiles derived from the outputs. The approach may be refined to ensure continuous variation of the decision variables with respect to the context variables where possible, in order to avoid jumping between values unnecessarily in case of the GP outputs exhibiting multimodal behaviour.

The trained GP model for the generated torque, or any of the probabilistic models trained to predict values of the performance characteristics, may have a large number of trainable parameters. The aim of training the models is to determine values of the trainable parameters for which the models best predict values of the performance characteristics, for given values of the context variables and the decision variables (for example as defined using maximum likelihood estimation or maximum a posteriori estimation). GP models provide a powerful and flexible means of inferring statistical information from the empirical data, and are particularly well-suited to situations in which data is sparse and/or costly to obtain, which is typically the case for test bench experiments on a powertrain of an electric vehicle 100.

It will be appreciated that the test bed experiments may be performed using a control system separate from the data processing system performing the method 500, for example at a different location and possibly controlled by a different commercial entity. For example, the experiments may be performed by a vehicle manufacturer and the data processing system guiding the experimentation may be operated by a third party. In this case, the data processing system guiding the experimentation may process data points from a remote system, and generate recommendations of variable values to be sent to the remote system for further experimentation. The entity operating the data processing system may not need to be provided full details of the experimental setup or even the physical details of all of the parameters, variables, and performance characteristics, provided the relevant constraints on the performance characteristics are provided, allowing the entity performing the experiments to avoid sharing sensitive information.

The above embodiments are to be understood as illustrative examples of the invention. Further embodiments of the invention are envisaged. For example, the methods described herein may be used to calibrate control units for vehicles with IC engines or for hybrid systems, or indeed for any task in which it is required to determine mappings from context variables to decision variables. Furthermore, the systems and methods described herein may be used to calibrate an ECU based on data generated completely or in part using a numerical simulator for the powertrain of an electric vehicle or one or more of its components. In such cases, the steps of obtaining measurements of powertrain performance characteristics may be replaced with obtaining data from the numerical simulator representing simulated values of the powertrain performance characteristics.

It is to be understood that any feature described in relation to any one embodiment may be used alone, or in combination with other features described, and may also be used in combination with one or more features of any other of the embodiments, or any combination of any other of the embodiments. Furthermore, equivalents and modifications not described above may also be employed without departing from the scope of the invention, which is defined in the accompanying claims.

What is claimed is:

1. A system comprising:
a test bench comprising:
a plurality of sensors for measuring values of a performance characteristic of a powertrain of an electric vehicle; and
a plurality of controllers for adjusting values of a plurality of variables associated with the operation of the powertrain, the plurality of variables including:
a set of context variables representing operational conditions of the electric vehicle; and
a set of decision variables representing parameters of the powertrain adjustable by an ECU of the electric vehicle; and
a data system comprising at least one processor and at least one non-transitory storage medium holding instructions which, when executed by the at least one processor, causes the data processing system to carry out operations comprising:
obtaining, from the test bench, measurements of the performance characteristic of the powertrain at one or more test points in an input space, the input space having dimensions corresponding to at least one context variable of the set of context variables and at least one decision variable of the set of decision variables;
training, using the obtained measurements of the performance characteristic at the one or more test points, a Gaussian process model arranged to predict values of the performance characteristic, wherein the Gaussian process model has a covariance function with a specified dependence on points in the input space, the specified dependence corresponding to a specified physical relationship between the performance characteristic and at least a chosen variable associated with the powertrain, the chosen variable being taken from the set of decision variables or the set of context variables; and
generating, in dependence on outputs of the trained Gaussian process model, a calibration map for the powertrain, the calibration map providing a mapping from values of the set of context variables to mapped values of the set of decision variables.

2. A method of generating a calibration map for a powertrain of an electric vehicle,
wherein the calibration map provides a mapping from values of a set of context variables to mapped values of a set of decision variables, the context variables having values representing operational conditions of the electric vehicle, the decision variables representing parameters of the powertrain adjustable by an electronic control unit (ECU) of the electric vehicle,
the method comprising, using at least one processor, determining the mapped values of the set of decision variables in dependence on outputs of a Gaussian process model arranged to predict values of a performance characteristic of the powertrain at points in an input space having dimensions corresponding to at least one context variable of the set of context variables and at least one decision variable of the set of decision variables,
wherein the Gaussian process model has a covariance function with a specified dependence on points in the input space, the specified dependence corresponding to a specified physical relationship between the performance characteristic and at least a chosen variable associated with the powertrain, the chosen variable being taken from the set of decision variables or the set of context variables.

3. The method of claim 2, further comprising:
obtaining measurements of the performance characteristic of the powertrain at one or more test points in the input space; and
updating the Gaussian process model to fit to the obtained measurements,
wherein determining the mapped values of the set of decision variables is in dependence on outputs of the trained Gaussian process model.

4. The method of claim 2, wherein the performance characteristic is a torque generated by the powertrain.

5. The method of claim 4, wherein the mapped values of the set of decision variables are determined based at least in part on the Gaussian process model predicting corresponding values of the generated torque to be in a proximity of a target torque value.

6. The method of claim 2, wherein the covariance function depends on locations of points in the input space along a dimension corresponding to the chosen variable.

7. The method of claim 2, wherein the powertrain comprises:
a battery for supplying a direct current and a direct voltage;
an inverter for converting the direct current to an alternating current; and
an electric motor that uses the alternating current to generate the torque, the electric motor comprising a stator configured to generate a first magnetic field using the alternating current and a rotor configured to generate a second magnetic field,
wherein:
the alternating current is representable by a first current parameter and a second current parameter; and
the chosen variable indicates the first current parameter.

8. The method of claim 7, wherein:
the first current parameter is an advance angle of the alternating current and the second current parameter is an amplitude of the alternating current, the advance angle representing an angle of the first magnetic field relative to the second magnetic field; and
the chosen variable indicates the advance angle of the alternating current, the generated torque having a sinusoidal dependence on the advance angle.

9. The method of claim 8, wherein determining the mapped values of the set of decision variables comprises:
predicting a feasible region of a decision space having dimensions corresponding to the amplitude and the advance angle of the alternating current, points in the feasible region satisfying an achievability criterion; and
selecting the mapped values of the amplitude and the advance angle of the alternating current from within the predicted feasible region of the decision space,
wherein the achievability criterion is satisfied when a value of the amplitude of alternating current and a value of the advance angle of the alternating current are achievable for a given value of the direct voltage.

10. The method of claim 9, wherein predicting the feasible region of the decision space comprises:
configuring a probabilistic voltage constraint model to predict values of the direct voltage at points in the decision space, the voltage constraint model having an associated mean function expressing the direct voltage in terms of the amplitude of the alternating current and the advance angle of the alternating current according to an indicated mathematical relationship; and
predicting the feasible region as a region of the decision space for which values of the direct voltage predicted by the voltage constraint model are less than a utilisation value.

11. The method of claim 2, wherein determining the mapped values of the set of decision variables comprises:
configuring a probabilistic model to estimate values of an efficiency of the powertrain, the mapped values of the set of decision variables being determined further in dependence on outputs of the probabilistic model.

12. The method of claim 11, wherein the powertrain comprises:
a battery for supplying a direct current and a direct voltage;
an inverter for converting the direct current to an alternating current; and
an electric motor that uses the alternating current to generate the torque, the electric motor comprising a stator configured to generate a first magnetic field using the alternating current and a rotor configured to generate a second magnetic field,
wherein:
the alternating current is representable by a first current parameter and a second current parameter; and
the chosen variable indicates the first current parameter.

13. The method of claim 12, wherein:
the Gaussian process model is a first Gaussian process model;
the probabilistic model comprises the first Gaussian process model and a second Gaussian process model arranged to predict values of the direct current supplied by the battery, and
determining a given output of the probabilistic model comprises:
determining a first Gaussian distribution in dependence on the first Gaussian process model;
determining a second Gaussian distribution in dependence on the second Gaussian process model; and
obtaining a set of probabilistic samples for the efficiency, each sample in the set of probabilistic samples representing a ratio of a sample from the first Gaussian distribution and a sample from the second Gaussian distribution; and
determining the given output of the probabilistic model in dependence on the set of probabilistic samples for the efficiency,
wherein obtaining the set of probabilistic samples for the efficiency comprises filtering the set of probabilistic samples to retain samples having values in a predefined range.

14. The method of claim 12, wherein determining a given output of the probabilistic model comprises:
determining a likelihood distribution for the probabilistic model in dependence on a first distribution over a first random variable representing the generated torque and a second distribution over a second random variable representing the direct current supplied by the battery, wherein the first and the second random variables are linearly related;
determining a posterior distribution for the probabilistic model in dependence the determined likelihood distribution and a prior distribution configured to output samples from a fixed interval of values; and
determining the given output of the probabilistic model in dependence on samples of the posterior distribution.

15. The method of claim 7, wherein the specified physical relationship further relates the performance characteristic to one or more of a motor speed of the electric motor, the direct voltage, and/or the second current parameter.

16. The method of claim 2, wherein the context variables include a temperature variable indicating a temperature of a component of the powertrain, and the method further comprises, using at least one processor:
training the Gaussian process model, the training comprising,
for each iteration in a set of one or more iterations:
obtaining a reference value of the temperature variable depending on a measurement of the temperature of the component of the powertrain;
selecting one or more points in a region of the input space in dependence on values of an acquisition function dependent on the Gaussian process model, the region of the input space being specified by the reference value of the temperature variable; and
acquiring data indicating, for each point of the one or more points, a respective set of measurements of the performance characteristic at values of the at least one context variable and the at least one decision variable corresponding to that point; and
updating the Gaussian process model in dependence on the data acquired during the set of one or more iterations,
wherein the mapped values of the set of decision variables are determined in dependence on outputs of the trained Gaussian process model.

17. The method of claim 16, wherein the covariance function is dependent on the temperature variable.

18. The method of claim 3, wherein training the Gaussian Process model comprises training a plurality of component Gaussian Process models, each component Gaussian Process model being trained on a respective portion of the acquired data.

19. The method of claim 2, further comprising configuring the electric vehicle with the generated calibration map.

20. One or more non-transitory storage media holding computer-readable instructions which, when executed by the at least one processor, cause the at least one processor to carry out a method of generating a calibration map for a powertrain of an electric vehicle, wherein the calibration map provides a mapping from values of a set of context variables to mapped values of a set of decision variables, the context variables having values representing operational conditions of the electric vehicle, the decision variables representing parameters of the powertrain adjustable by an electronic control unit (ECU) of the electric vehicle,
the method comprising, using at least one processor, determining the mapped values of the set of decision variables in dependence on outputs of a Gaussian process model arranged to predict values of a performance characteristic of the powertrain at points in an input space having dimensions corresponding to at least one context variable of the set of context variables and at least one decision variable of the set of decision variables,
wherein the Gaussian process model has a covariance function with a specified dependence on points in the input space, the specified dependence corresponding to a specified physical relationship between the performance characteristic and at least a chosen variable associated with the powertrain, the chosen variable being taken from the set of decision variables or the set of context variables.
